(19) United States
(12) Patent Application Publication
(10) Pub. No.: US 2020/0142537 A1
(43) Pub. Date: May 7, 2020

(54) TOUCH PANEL AND DISPLAY DEVICE

(71) Applicant: BOE TECHNOLOGY GROUP CO., LTD., Beijing (CN)

(72) Inventor: Tawei KUO, Beijing (CN)

(73) Assignee: BOE TECHNOLOGY GROUP CO., LTD., Beijing (CN)

(21) Appl. No.: 16/413,047

(22) Filed: May 15, 2019

(30) Foreign Application Priority Data
Nov. 2, 2018 (CN) 201811302412.5

(51) Int. Cl. G06F 3/044; H01L 27/32; H01L 51/00

(52) U.S. Cl. CPC G06F 3/0443; H01L 27/3244; H01L 27/323; H01L 2251/5338; G06F 2203/04102; G06F 2203/04112; H01L 51/0097

(57) ABSTRACT

A touch panel and a display device are provided. The touch panel includes a substrate, and a signal line, a dielectric layer and a sensing electrode provided on the substrate, wherein the dielectric layer is located between the signal line and the sensing electrode, the sensing electrode is connected with the signal line through a via hole in the dielectric layer.

This application claims priority to the Chinese patent application No. 201811302412.5 filed on Nov. 2, 2018, the entire disclosure of which is incorporated herein by reference as part of the present application.

### TECHNICAL FIELD

The disclosure relates to a touch panel and a display device.

### BACKGROUND

With the emergence and continuous development of OLED (Organic Light-Emitting Diode) display technology, flexible screens that can be bent and curled are widely used in mobile phones and flat panels. It can be imagined that ultra-thin stack thickness and bend ability will become the future development trend.

Ultra-thin stacks such as flexible AMO LED (Active-Matrix Organic Light Emitting Diode) display screens are prone to large-area scribing and disconnection, bifurcation lines, false alarms and other phenomena in a low grounding environment. In general, the self-capacitance sensing method is adopted to solve the problem. However, the existing single-layer square pattern design of pure self-capacitance sensors obviously affects the size of supporting copper pillar phi and the linearity performance.

### SUMMARY

At least one embodiment of the disclosure provides a touch panel comprising: a substrate, and a signal line, a dielectric layer and a sensing electrode provided on the substrate, wherein the dielectric layer is located between the signal line and the sensing electrode, the sensing electrode is connected with the signal line through a via hole in the dielectric layer.

In some examples, an orthographic projection of the sensing electrode on the substrate partially overlaps with an orthographic projection of the signal line on the substrate.

In some examples, the sensing electrode comprises a plurality of sensing electrodes, the signal line comprises a plurality of signal lines, the plurality of sensing electrodes correspond to the plurality of signal lines one by one, and each of the plurality of sensing electrodes is connected with a corresponding signal line.

In some examples, the plurality of sensing electrodes are arrayed along a row direction and a column direction parallel to the substrate to form a plurality of sensing electrode rows and a plurality of sensing electrode columns, the plurality of signal lines extend in the column direction, and orthographic projections of intervals between adjacent sensing electrode columns on the substrate do not overlap orthographic projections of the plurality of signal lines on the substrate.

In some examples, a size of the interval between adjacent sensing electrode rows is larger than that between adjacent sensing electrode columns.

In some examples, the sensing electrode is in a square shape, and the square has a side length of 3.3 mm to 4.5 mm.

In some examples, the signal line and the sensing electrode are both metal structures.

In some examples, the metal structure comprises at least one of a single-layer metal and a multi-layer metal.

In some examples, the dielectric layer comprises at least one of an inorganic dielectric layer and an organic dielectric layer.

In some examples, the inorganic dielectric layer has a thickness of 2500 Å to 4000 Å.

In some examples, the organic dielectric layer has a thickness of 1 μm to 2 μm.

In some examples, the sensing electrode is self-capacitance sensor.

At least one embodiment provides a display device comprising a display panel and the touch panel as mentioned above.

In some examples, the display panel comprises at least one of a flexible active-matrix organic light emitting diode (AMOLED) display panel and a hard AMOLED display panel.

In some examples, the sensing electrode is a self-capacitance sensor.

### BRIEF DESCRIPTION OF THE DRAWINGS

In order to clearly illustrate the technical solution of the embodiments of the invention, the drawings of the embodiments will be briefly described in the following; it is obvious that the described drawings are only related to some embodiments of the invention and thus are not limitative of the invention.

FIG. 1 illustrates a schematic structural diagram of a touch panel according to an embodiment of the disclosure;

FIG. 2 illustrates a cross-sectional view of a touch panel according to an embodiment of the disclosure;

FIG. 3 illustrates a schematic structural diagram of a touch panel according to an embodiment of the disclosure; and

FIG. 4 illustrates a schematic structural diagram of a display device according to an embodiment of the disclosure.

### DETAILED DESCRIPTION

In order to make objects, technical details and advantages of the embodiments of the invention apparent, the technical solutions of the embodiment will be described in a clearly and fully understandable way in connection with the drawings related to the embodiments of the invention. It is obvious that the described embodiments are just a part but not all of the embodiments of the invention. Based on the described embodiments herein, those skilled in the art can obtain other embodiment(s), without any inventive work, which should be within the scope of the invention.

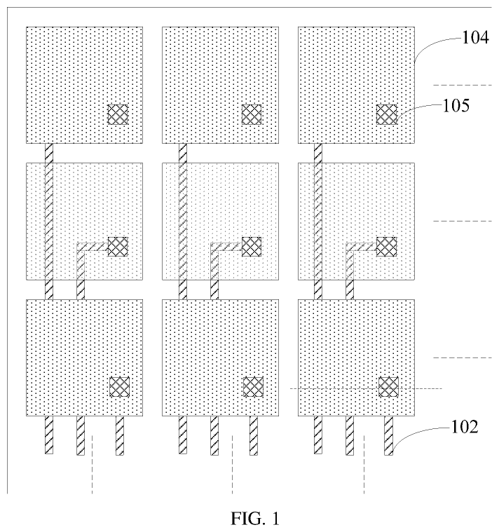

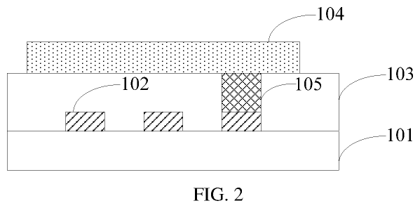

Referring to FIG. 1, a schematic structural diagram of a touch panel provided by an embodiment of the present disclosure is illustrated. The touch panel 10 includes a substrate 101 (please refer to FIG. 2), a signal line 102, a dielectric layer 103, and a sensing electrode 104. The signal line 102 is disposed on the substrate 101; the dielectric layer 103 covers the signal line 102. A plurality of sensing electrodes 104 are arranged on the dielectric layer 103, and each of the sensing electrodes 104 is connected with a corresponding signal line 102 through a via hole 105 in the dielectric layer 103. For example, the orthographic projection of the sensing electrode 104 on the substrate 101 partially overlaps with the orthographic projection of the signal line 102 on the substrate 101.

As illustrated in FIG. 1, the sensing electrode 104 includes a plurality of sensing electrodes, and the signal line 102 includes a plurality of signal lines. The plurality of sensing electrodes correspond to the plurality of signal lines one by one, and each of the plurality of sensing electrodes is connected with a corresponding signal line.

For example, a plurality of sensing electrodes are arrayed in a row direction and a column direction parallel to the substrate to form a plurality of sensing electrode rows and a plurality of sensing electrode columns. The plurality of signal lines extend in the column direction, and the orthographic projection of the interval between adjacent sensing electrode columns on the substrate does not overlap with the orthographic projection of the plurality of signal lines on the substrate.

In this embodiment, referring to the cross-sectional view at the dotted line AA′ in FIG. 1 shown in FIG. 2, the signal line 102 is provided on the substrate 101. The substrate 101 may include other circuit structures of the touch panel 10. The embodiment of the present disclosure is not limited to thereto in detail, and may be set according to actual conditions. The dielectric layer 103 covers the signal lines 102, the via holes 105 are provided in the dielectric layer 103, and the sensing electrodes 104 are arranged on the dielectric layer 103. The sensing electrode 104 is, for example, a self-contained sensing sensor, and is connected to the corresponding signal line 102 through the via hole 105. The orthographic projection of the sensing electrode 104 on the substrate 101 partially overlaps with the orthographic projection of the signal line 102 on the substrate 101. For example, the sensing electrode 104 and the signal line 102 are arranged in a grid shape.

Since the sensing electrode 104 and the signal line 102 form an upper layer and a lower layer structure, the sensing electrodes 104 can be closely arranged on the dielectric layer 103, so that the effective sensing area on the touch panel is larger. In addition, there is no invalid sensing region between adjacent sensing electrodes 104. Since there is no invalid sensing area, it can support projective capacitive active pens and passive pens under 2 phi to obtain better linearity performance.

In some related technologies, sensing electrodes and signal lines are arranged on the same layer, and the signal lines need to be arranged between adjacent sensing electrodes, so there is an invalid sensing area between adjacent sensing electrodes. When water drops or small objects fall on the touch panel, the touch panel cannot detect the water drops or small objects falling on the invalid sensing area. However, in the embodiment of the present disclosure, there is no invalid sensing area, and when water drops on the touch panel, the touch panel can more sensitively detect water drops or smaller objects. According to this characteristic, the designed touch panel can achieve better waterproof effect and detect smaller objects.

In some related technologies, the invalid sensing area is large, so the touch of gloves or active pens cannot be detected. However, in the embodiment of the present disclosure, there is no invalid sensing area, so the sensing amount can be greatly increased, and the touch of gloves or active pens can be detected, that is, the accuracy of the touch panel is improved.

In the embodiment of the present disclosure, since the sensing electrode 104 and the signal line 102 are arranged on different layers, the gap between adjacent sensing electrodes 104 can be reduced, thereby reducing or eliminating invalid sensing regions and widening the application field of the touch panel.

Optionally, each sensing electrode 104 is in a square shape. For example, the side length of the square is 3.3 mm to 4.5 mm. However, the embodiments according to the present disclosure are not limited thereto, and the sensing electrode may be rectangular or any other suitable shapes.

In this embodiment, the sensing electrode 104 may be rectangular, such as square. The side length of the square is 3.3 mm to 4.5 mm.

Optionally, both the signal line 102 and the sensing electrode 104 are metal structures.

Optionally, the metal structure includes at least one of a single-layer metal and a multi-layer metal.

In this embodiment, the signal line 102 and the sensing electrode 104 are both metal structures, and the metal structure may be a single layer of metal, such as copper and molybdenum; it can also be a multi-layer metal, such as Ti/Al/Ti, Mo/Al/Mo. The embodiments of the present disclosure are not limited to this in detail, and may be set according to actual conditions.

Optionally, the dielectric layer 103 includes at least one of an inorganic dielectric layer and an organic dielectric layer.

Optionally, the inorganic dielectric layer has a thickness of 2500 Å to 4000 Å.

Optionally, the thickness of the organic dielectric layer is 1 μm to 2 μm.

In this embodiment, the dielectric layer 103 acts as an isolation between the signal line 102 and the sensing electrode 104, prevents mutual interference between the signal line 102 and the sensing electrode 104, and ensures that each sensing electrode 104 is only electrically connected to its corresponding signal line. In order to play a role of isolation, 2500 Å-4000 Å inorganic dielectric layers or 1 μm-2 μm organic dielectric layers can be used. The inorganic dielectric layer may be SiNₓ or SiO₂. The embodiment of the present disclosure is not limited to this in detail, and may be set according to actual conditions.

In the embodiment of the disclosure, the touch panel comprises a substrate, a signal line, a dielectric layer and a sensing electrode; the signal line is arranged on the substrate; the dielectric layer covers the signal line. A plurality of sensing electrodes are arranged in an array on the dielectric layer, and the sensing electrodes are connected with corresponding signal lines through via holes in the dielectric layer. Since the sensing electrodes are closely arranged and the signal lines are located below the sensing electrodes, the invalid sensing area between adjacent sensing electrodes is very small, which not only enables the touch panel to be supported by copper pillars with smaller phi number, better linearity efficiency, but also improves the accuracy of the touch panel.

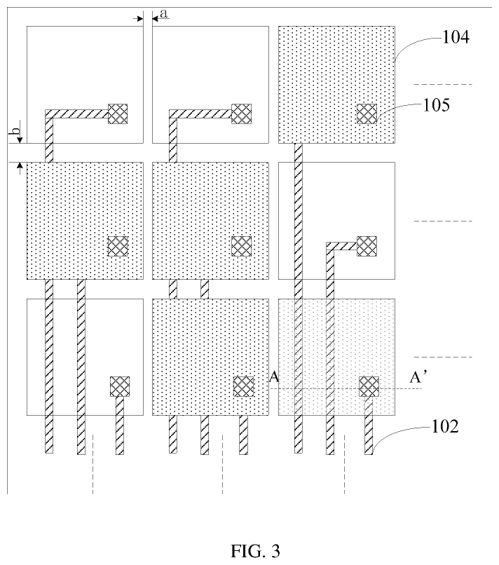

In some embodiments, since the sensing electrodes and the signal lines are disposed at different layers, there is no need to leave a space for disposing the signal lines between adjacent sensing electrode columns Therefore, the interval between adjacent sensing electrode columns can be set small. For example, as illustrated in FIG. 3, the spacing dimension a between adjacent sensing electrode columns is smaller than the spacing dimension b between adjacent sensing electrode rows. The invalid sensing region can be further reduced by further reducing the interval between adjacent sensing electrodes in the region where signal lines are not provided.

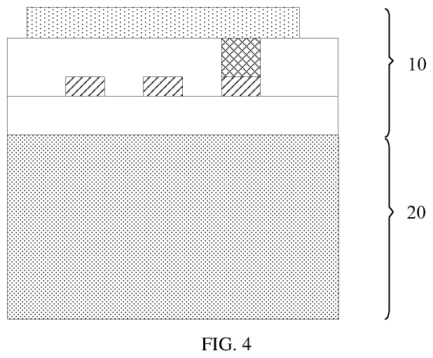

Referring to FIG. 4, an embodiment of the present disclosure provides a display device. The display device includes a display panel 20 and a touch panel 10 as described above. For example, the touch panel 10 may be disposed on the display surface side of the display panel 20.

In this embodiment, the touch panel 10 includes a substrate 101, a signal line 102, a dielectric layer 103, and a sensing electrode 104. A signal line 102 is provided on the substrate 101; the dielectric layer 103 covers the signal line 102. A plurality of the sensing electrodes 104 are arranged on the dielectric layer 103, and the sensing electrodes 104 are connected with corresponding signal lines 102 through via holes 105 in the dielectric layer 103. For example, the orthographic projection of the sensing electrode 104 on the substrate 101 partially overlaps with the orthographic projection of the signal line 102 on the substrate 101. Since the sensing electrode 104 and the signal line 102 form an upper layer and a lower layer structure, the sensing electrodes 104 can be closely arranged on the dielectric layer 103, so that the effective sensing area on the touch panel is larger, and there is no invalid sensing area between adjacent sensing electrodes 104. Since there is no invalid sensing area, it can support projective capacitive active pens and passive pens under 2 phi to obtain better linearity performance.

In some related technologies, signal lines are provided between adjacent sensing electrodes, so the invalid sensing area between adjacent sensing electrodes is larger. When water drops on the touch panel, the touch panel cannot detect water drops falling on the invalid sensing area. However, in the embodiment of the present disclosure, there is no invalid sensing area, and when water drops on the touch panel, the touch panel can detect water drops. According to this characteristic, the touch panel can achieve waterproof and moisture-proof effects.

In some related technologies, the invalid sensing area is large, so the touch of gloves or active pens cannot be detected. However, in the embodiment of the present disclosure, there is no invalid sensing area, so the touch of gloves or active pens can be detected, that is, the accuracy of the touch panel is improved.

The touch panel 10 can cooperate with the display panel 20 to form a display device. The sensing electrode 104 and the signal line 102 in the touch panel 10 are both arranged in a grid shape and avoid the light emitting area of the display panel 20.

Optionally, the display panel 20 includes at least one of a flexible AMOLED (Active-Matrix Organic Light Emitting Diode) display panel and a hard AMOLED display panel. For example, the flexible AMOLED display panel is prone to large-area disconnection or bifurcation under weak grounding environment, and may also have the phenomenon of multiple false positives. In the touch panel 10 described in the above embodiment, the sensing electrode 104 is a self-capacitance sensor, which can solve the above problems of the flexible AMOLED display panel, so the touch panel and the flexible AMOLED display panel can form a display device. In the future, flexible AMOLED display panels that can be bent and curled will be widely applied to mobile terminals. The touch panel in the embodiment of the present disclosure has a wider application prospect.

The touch panel and the hard AMOLED display panel can also form a display device, thus improving the accuracy of the display device. The embodiments of the present disclosure are not limited to this in detail, and may be set according to actual conditions.

In the embodiment of the disclosure, the display device comprises a display panel and a touch panel, and the touch panel can solve the problems that the flexible AMOLED display panel is prone to large-area disconnection, bifurcation lines and false alarm multipoint in a weak grounding environment, and improve the accuracy of the display device.

Each embodiment in this specification is described in a progressive manner. What each embodiment focuses on is the difference from other embodiments. The same and similar parts between each embodiment can be referred to each other.

Finally, it should also be noted that in this document, relational terms such as first and second, etc. are only used to distinguish one entity or operation from another entity or operation, and do not necessarily require or imply any such actual relationship or order between these entities or operations. Moreover, the terms “comprising,” “comprising,” or any other variation thereof, are intended to cover a non-exclusive inclusion, such that a process, method, article, or apparatus that comprises a list of elements includes not only those elements but also other elements not expressly listed or elements inherent to such process, method, article, or apparatus. Without further restrictions, an element defined by the statement “includes a (an) . . . ” does not exclude the presence of another identical element in a process, method, article, or device that includes the element.

The above description is merely an exemplary embodiment of the present invention and is not intended to limit the scope of protection of the present invention, which is determined by the appended claims.

1. A touch panel comprising:
a substrate, and a signal line, a dielectric layer and a sensing electrode provided on the substrate, wherein
the dielectric layer is located between the signal line and the sensing electrode,
the sensing electrode is connected with the signal line through a via hole in the dielectric layer.

2. The touch panel according to claim 1, wherein an orthographic projection of the sensing electrode on the substrate partially overlaps with an orthographic projection of the signal line on the substrate.

3. The touch panel according to claim 1, wherein the sensing electrode comprises a plurality of sensing electrodes, the signal line comprises a plurality of signal lines, the plurality of sensing electrodes correspond to the plurality of signal lines one by one, and each of the plurality of sensing electrodes is connected with a corresponding signal line.

4. The touch panel according to claim 3, wherein the plurality of sensing electrodes are arrayed along a row direction and a column direction parallel to the substrate to form a plurality of sensing electrode rows and a plurality of sensing electrode columns,
the plurality of signal lines extend in the column direction, and orthographic projections of intervals between adjacent sensing electrode columns on the substrate do not overlap orthographic projections of the plurality of signal lines on the substrate.

5. The touch panel according to claim 4, wherein a size of the interval between adjacent sensing electrode rows is larger than that between adjacent sensing electrode columns.

6. The touch panel according to claim 1, wherein the sensing electrode is in a square shape, and the square has a side length of 3.3 mm to 4.5 mm.

7. The touch panel of claim 1, wherein the signal line and the sensing electrode are both metal structures.

8. The touch panel of claim 7, wherein the metal structure comprises at least one of a single-layer metal and a multi-layer metal.

9. The touch panel according to claim 1, wherein the dielectric layer comprises at least one of an inorganic dielectric layer and an organic dielectric layer.

10. The touch panel according to claim 9, wherein the inorganic dielectric layer has a thickness of 2500 Å to 4000 Å.

11. The touch panel according to claim 9, wherein the organic dielectric layer has a thickness of 1 μm to 2 μm.

12. The touch panel according to claim 1, wherein the sensing electrode is self-capacitance sensor.

13. A display device comprising a display panel and the touch panel according to claim 1.

14. The display device according to claim 13, wherein the display panel comprises at least one of a flexible active-matrix organic light emitting diode (AMOLED) display panel and a hard AMOLED display panel.

15. The display device according to claim 13, wherein the sensing electrode is a self-capacitance sensor.
